(19) United States
(12) Patent Application Publication
(10) Pub. No.: US 2013/0249655 A1
(43) Pub. Date: Sep. 26, 2013

(54) VARIABLE CAPACITOR CIRCUIT

(71) Applicant: SAMSUNG ELECTRO-MECHANICS CO., LTD., Gyeonggi-do (KR)

(72) Inventor: Jae Hyouck Choi, Gyeonggi-do (KR)

(73) Assignee: SAMSUNG ELECTRO-MECHANICS CO., LTD., Gyeonggi-do (KR)

(21) Appl. No.: 13/794,681

(22) Filed: Mar. 11, 2013

(30) Foreign Application Priority Data
Mar. 21, 2012 (KR) 10-2012-0028830

(51) Int. Cl. H03H 7/00

(52) U.S. Cl. CPC H03H 7/004
USPC 333/24 C

(57) ABSTRACT

Disclosed herein is a variable capacitor circuit. The variable capacitor circuit which is composed of a plurality of capacitors and a switch transistor connected to each capacitor, and adjusts a capacitance value (C) in accordance with ON/OFF of the switch transistor, includes a unit cell in which at least one switching unit and at least one capacitor are alternately connected in series to each other, and a plurality of capacitor units to which at least one of the unit cells is connected in parallel, and thereby may adjust a difference in quality factors in accordance with a signal direction.

### CROSS REFERENCE(S) TO RELATED APPLICATIONS

This application claims the benefit under 35 U.S.C. Section 119 of Korean Patent Application Serial No. 10-2012-0028830, entitled “Variable Capacitor Circuit” filed on Mar. 21, 2012, which is hereby incorporated by reference in its entirety into this application.

### BACKGROUND OF THE INVENTION

1. Technical Field

The present invention relates to a variable capacitor circuit, and more particularly, to a variable capacitor circuit which may adjust a difference in quality factors in accordance with a signal direction.

2. Description of the Related Art

In wireless communication such as a mobile device, and the like, a variety of frequency band signals having mutually different stipulated transmission power levels of various frequency bands exist. For example, in a case of a Universal Mobile Telecommunication System (UMTS) that is the third generation standard having an improved transfer speed in comparison with the second generation standard, a variety of segmented frequency bands exist, such as BAND 1 (transmission frequency band: 1920 to 1980 MHz) which is used in most countries except the United States, BAND 2 (transmission frequency band: 1850 to 1910 MHz) which is used in North America and South America, BANDs 4 and 10 (transmission frequency bands: 1710 to 1770 MHz) which is used in some areas of the United States and Canada, BAND 5 (transmission frequency band: 824 to 849 MHz) which is used in specific areas of the United States and Oceania, and BAND 8 (transmission frequency band: 880 to 915 MHz) which is used in Europe, Asia, and Oceania, etc., and the like.

In addition, in a case of a Global System for Mobile communication (GSM) that is one of the second communication standards, a variety of segmented frequency bands exist, such as GSM 900 (transmission frequency band: 880 to 915 MHz) which is used in most countries that adopt GSM, DCS 1800 (transmission frequency band: 1710 to 1785 MHz), GSM 850 (transmission frequency band: 824 to 849 MHz) which is used in several countries including the United States and Canada, PCS 1900 (transmission frequency band: 1850 to 1910 MHz), and the like.

In addition, in recent years, the fourth generation mobile communication advocated as Long Term Evolution (LTE) has emerged. In this manner, as the fourth generation mobile communication network is added to the third generation mobile communication network, the number of methods that is required to be supported in a single mobile phone has increased.

In response to these technical requirements, it is necessary to provide a transmission circuit within a mobile terminal in which a transmission circuit of the mobile terminal may selectively transmit wireless communication signals of a desired frequency band at an appropriate power level. In addition, by optimizing a front-end matching including an antenna while using a mobile phone, it is necessary to optimize power consumed in a Power Amplifier (PA), and to optimize a reception rate of a Low Noise Amplifier (LNA).

In order to implement such functions, a Tunable Matching Network (TMN) circuit is required to be added to an RF front-end having an existing fixed structure, thereby obtaining flexibility. A variable reactance element is used as an adjusting element of the TMN circuit, and particularly, a variable capacitor is frequently used.

Among variable capacitors having various schemes, many researches on a Metal-Insulator-Metal (MIM) scheme having a cost advantage have been conducted. In this regard, as disclosed in Korean Patent Laid-Open Publication No. 10-2006-0075660 (hereinafter, referred to as “Related Art Document”), a variable capacitor circuit which controls capacitance between an input node and an output node by controlling, using a switching transistor, a plurality of capacitors to be connected in series, and the capacitors to be connected between the input node and the output node have been proposed.

Although, reversibility and a quality factor of the variable capacitor are important factors in the TMN circuit; however, reversibility and a quality factor of the TMN circuit may not be improved by the variable capacitor circuit proposed in Related Art Document.

The variable capacitor circuit proposed in the Related Art Document includes a plurality of switching transistors TR1, TR2, TR3, and TR4, and capacitors C1, C2, C3, and C4 which are respectively connected to the plurality of switching transistors. In this manner, in the variable capacitor circuit of the prior art, a unit cell having a fixed structure which is composed of a single transistor and a single capacitor is applied, so that a difference between an impedance (Z+) in each unit cell when signals are transmitted from the output node to the input node and an impedance (Z−) in each unit cell when signals are transmitted from the input node to the output node may exist, and a parameter capable of adjusting the difference does not exist in the unit cell having the fixed structure, thereby failing to adjust a difference in quality factors of the variable capacitor circuit.

### RELATED ART DOCUMENT

### Patent Document

Patent Document 1. Korean Patent Laid-Open Publication No. 10-2006-0075660

### SUMMARY OF THE INVENTION

An object of the present invention is to provide a variable capacitor circuit that may adjust a difference in quality in accordance with a signal direction.

According to an exemplary embodiment of the present invention, there is provided a variable capacitor circuit, including: a unit cell in which at least one switching unit and at least one capacitor are alternately connected in series to each other; and a plurality of capacitor units to which at least one of the unit cells is connected in parallel, wherein a capacitance value (C) is adjusted in accordance with ON/OFF of the switching unit in a manner such that an end of each of the plurality of capacitor units is connected to a first node, and the other end thereof is connected to a second node.

In this instance, the number of unit cells included in each capacitor unit may be mutually different for each capacitor unit.

In addition, the number of switching units and the capacitors included in each unit cell may be mutually different for each unit cell.

Also, the switching unit may include at least one switch transistor which is connected in series, and the number of switch transistors may be mutually different for each switching unit.

Also, the number of unit cells included in each capacitor unit may be mutually different for each capacitor unit, the number of switching units and the capacitors which are included in each unit cell may be mutually different for each unit cell, the switching unit may include at least one switch transistor which is connected in series, and the number of switch transistors included in each switching unit may be mutually different for each switching unit.

Also, the capacitance value (C) of each unit cell may be 1.

Also, the capacitor may have a Metal Insulator Metal (MIM) structure.

Also, the variable capacitor circuit may further include a decoder having a plurality of output terminals which are connected to each of the plurality of capacitor units.

According to another exemplary embodiment of the present invention, there is provided a variable capacitor circuit which is composed of a plurality of capacitor units, wherein each capacitor unit includes at least one unit cell, the unit cell includes at least one switch transistor and at least one capacitor which are connected in series to each other, and a connection position of the capacitor is mutually different for each capacitor unit.

In this instance, the number of capacitors and switch transistors included in the unit cell may be mutually different for each unit cell.

In addition, the number of unit cells included in each capacitor unit may be mutually different for each capacitor unit.

In addition, the number of capacitors and switch transistors included in the unit cell may be mutually different for each capacitor unit, and the number of unit cells included in each capacitor unit may be mutually different for each capacitor unit.

According to still another exemplary embodiment of the present invention, there is provided a variable capacitor circuit which is composed of a plurality of capacitor units, wherein each capacitor unit includes at least one unit cell, the unit cell includes at least one switch transistor and at least one capacitor which are connected in series to each other, and a connection position of the capacitor is mutually different for each unit cell.

### BRIEF DESCRIPTION OF THE DRAWINGS

FIG. 1 is a detailed circuit diagram for explaining a first embodiment of the present invention;

FIGS. 2A and 2B are equivalent circuit diagrams illustrating a unit cell according to an embodiment of the present invention; and

FIG. 3 is a detailed circuit diagram for explaining a second embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the description denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

A variable capacitor circuit according to the present invention may include a unit cell in which at least one switching unit and at least one capacitor are alternately connected in series to each other, and a plurality of capacitor units including at least one of the unit cells.

Here, the capacitor preferably has a Metal Insulator Metal (MIM) structure, and the switching unit includes at least one switch transistor.

The switch transistor may be implemented as a PMOS transistor or an NMOS transistor. When the switching unit includes at least two switch transistors, the respective switch transistors are connected in series to each other through a source-drain.

Such the capacitor and the switching unit are alternately connected in series to each other to thereby form a single unit cell. Hereinafter, a structure of the capacitor and the switching unit which are alternately connected in series to each other will be described in detail. For example, a source terminal or a drain terminal of the switch transistor that is located at a first end of a first switching unit is connected to an end of a first capacitor, and an end of a second capacitor is connected to the drain terminal or the source terminal of the switch transistor that is located at a final end of the first switching unit. The source terminal or the drain terminal of the switch transistor that is located at a first end of a second switching unit is connected to the other end of the second capacitor, and in this manner, the capacitor and the switching unit are alternately connected in series to each other.

In this instance, when the capacitor and the switching unit are alternately connected in series to each other, the capacitor may be located at a first end of the unit cell, or otherwise, the switching unit may be located at the first end of the unit cell. In addition, when the capacitor is located at the first end of the unit cell, the switching unit or the capacitor may be located at a final end of the unit cell, or otherwise, when the switching unit is located at the first end of the unit cell, the switching unit or the capacitor may be located at the final end of the unit cell. That is, in a structure of the unit cell that is applied to the variable capacitor circuit according to the present invention, the fact that the capacitor and the switching unit are alternately connected in series to each other is important, and which element is located at the first end and the final end of the unit cell is not greatly affected.

In addition, the number of capacitors and switching units may be set to be different from each other for each unit cell. For example, when the total number of unit cells (first to third unit cells) is 3, the first unit cell may include a single capacitor and a single switching unit, the second unit cell may include two capacitors and two switching units, and the third unit cell may include three capacitors and three switching units.

However, in this instance, a capacitance value (C) of each unit cell is preferably “1”. In the unit cell, the capacitor and the switching unit are connected in series to each other, and therefore, the capacitors included in the unit cell are also connected in series. In the above described example, it is preferable that a capacitance value (C) of the capacitor included in the first unit cell including a single capacitor be “1”, a capacitance value (C) of the capacitor included in the second unit cell including two capacitors be “2”, and a capacitance value (C) of the capacitor included in the third unit cell including three capacitors be “3”.

In addition, the switching unit included in each unit cell may have different numbered-switch transistors for each switching unit. For example, when two switching units (first to second switching units) are included in a single unit cell, two switch transistors may be connected in series to the first switching unit, and three switch transistors may be connected in series to the second switching unit. When three switching units (third to fifth switching units) are included in the mutually different unit cells, four switch transistors may be connected in series to the third switching unit, five switch transistors may be connected in series to the fourth switching unit, and six switch transistors may be connected in series to the fifth switching unit.

In this manner, when each unit cell includes mutually different numbered-capacitors and switching units, when each unit cell includes mutually different numbered-switch transistors for each switching unit, or when each unit cell includes mutually different numbered-capacitors and switching units and mutually different numbered-switch transistors for each switching unit, the variable capacitor circuit according to the present invention may adjust a difference in quality factors in accordance with a signal direction. This will be described in detail in the embodiments of the present invention, which will be described below. The variable capacitor circuit according to the present invention may include a plurality of capacitor units. Each capacitor unit includes at least one of the unit cells, and when each capacitor unit includes at least two unit cells, the respective unit cells are connected to each other in parallel.

Hereinafter, a structure of a plurality of unit cells which are connected to each other in parallel will be described in detail. For example, when a single capacitor unit includes two unit cells (first to second unit cells), a capacitor is located at a first end of the first unit cell, and the switching unit is located at a first end of the second unit cell, an end of the capacitor located at the first end of the first unit cell and an end (specifically, source terminal or drain terminal of the switch transistor) of the switching unit located at the first end of the second unit cell are connected to an a node, and elements located at a final end of the first unit cell and a final end of the second unit cell are connected to a b node, so that the first unit cell and the second unit cell are connected to each other in parallel. A case in which the signal capacitor unit includes the two unit cells has been described; however, even in a case in which the single capacitor unit includes at least three unit cells, the first unit cell and the second unit cell may be connected to each other in parallel in the same manner.

Meanwhile, the number of unit cells included in each capacitor unit may be set to be different for each capacitor unit. For example, when the number of capacitor units is four, a first capacitor unit may include a single unit cell, a second capacitor unit may include two unit cells, a third capacitor unit may include four unit cells, and a fourth capacitor unit may include eight unit cells.

In this manner, when a plurality of capacitor units includes mutually different numbered-unit cells, a capacitance value (C) of the variable capacitor circuit may be varied in a binary scheme.

In the above described example, when capacitance values (C) of the respective unit cells included in the first to fourth capacitor units are all “1”, a capacitance value (C) of the first capacitor unit including a single unit cell is “1”, a capacitance value (C) of the second capacitor unit including two unit cells is “2”, a capacitance value (C) of the third capacitor unit including four unit cells is “4”, and a capacitance value (C) of the fourth capacitor unit including eight unit cells is “8”, and therefore, the capacitance value (C) may be varied in the binary scheme in accordance with a control signal of a decoder which will be described below.

An end of each of the plurality of capacitor units is connected to a first node, and the other end thereof may be connected to a second node. The capacitor unit includes at least one unit cell, and unit cells within each capacitor units are connected to each other in parallel as described above, and therefore, all unit cells included in the variable capacitor circuit has a structure of being connected to each other in parallel through the first node and the second node.

Here, the first node may be an output node or an input node in a network (for example, TMN circuit) including the variable capacitor circuit of the present invention. Accordingly, when the first node is the output node, the second node may be the input node, and when the first node is the input node, the second node may be the output node.

The variable capacitor circuit of the present invention may include the decoder having a plurality of output terminals which are respectively connected to the plurality of capacitor units. Specifically, each output terminal of the decoder is connected to the switching unit of each capacitor unit, more specifically, to a gate terminal of the switch transistor included in the switching unit.

Hereinafter, a connection structure between the output terminal of the decoder and the capacitor unit will be described in detail. For example, in a case of a first output terminal connected to the first capacitor unit including the first unit cell, gate terminals of the switch transistor of the switching unit included in the first unit cell are all connected to the a node, and the first output terminal is also connected to the a node. Accordingly, ON/OFF of all switch transistors of the first capacitor unit which are connected to the first output terminal may be controlled in accordance with a control signal of the first output terminal of the decoder.

In this manner, each output terminal of the decoder is connected to each of the plurality of capacitor units one by one, and controls each capacitor unit, so that a capacitance value (C) of the variable capacitor circuit may be adjusted in accordance with an N-bit control signal of the decoder. Here, N denotes the number of capacitor units and the number of output terminals of the decoder, and for example, when N is 4, a control signal (b0) is output through a first output terminal, a control signal (b1) is output through a second output terminal, a control signal (b2) is output through a third output terminal, and a control signal (b3) is output through a fourth output terminal, thereby controlling the switch transistor of each capacitor unit.

Next, a specific embodiment of the variable capacitor circuit according to the present invention will be described with reference to drawings. A connection structure between respective components in an embodiment which will be described as below is the same as that of the above described variable capacitor circuit according to the present invention, and therefore, detailed descriptions thereof will be omitted as possible, and operations and effects thereof will be described.

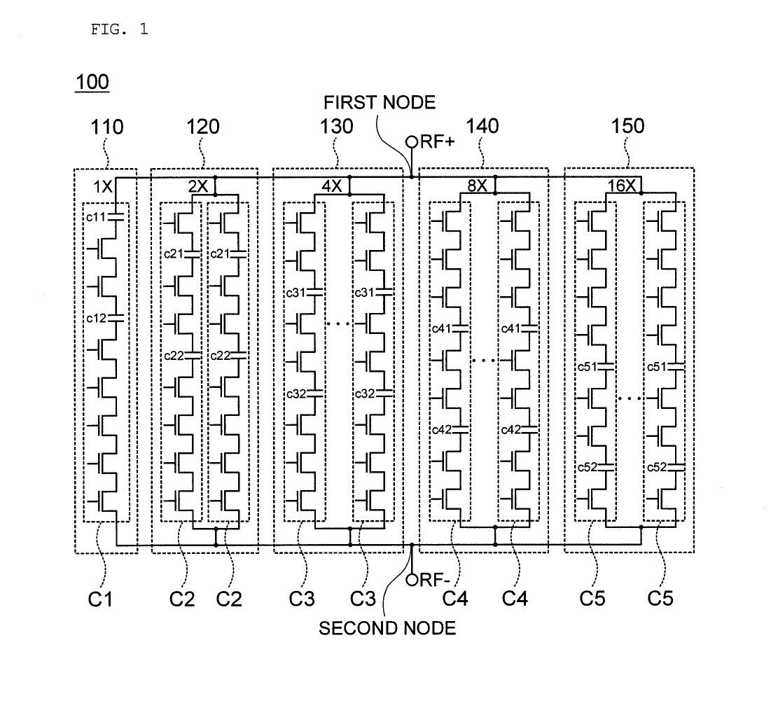

FIG. 1 is a detailed circuit diagram for explaining a first embodiment of the present invention.

Referring to FIG. 1, a first embodiment 100 of the present invention includes a plurality of capacitor units 110, 120, 130, 140, and 150, and each of the capacitor units 110, 120, 130, 140, and 150 includes at least one of the unit cells C1, C2, C3, C4, and C5. When each of the capacitor units 110, 120, 130, 140, and 150 includes at least two unit cells, respective unit cells are connected to each other in parallel.

For example, the unit cell C1 among the unit cells C1, C2, C3, C4, and C5 includes capacitors c11 and c12 connected in series and the switch transistor, and each of the number of capacitors and the number of switch transistors may be configured as at least one. A gate resistor (RG) is connected to a gate terminal of each switch transistor; however, is omitted for simplification of drawings.

In order that the capacitance value (C) of the variable capacitor circuit is varied in the binary scheme, the number of unit cells included in each of the capacitor units 110, 120, 130, 140, and 150 may be set to be different for each capacitor unit, and in this instance, a capacitance value (C) of each unit cell is preferably “1”.

An end of each of the plurality of capacitor units 110, 120, 130, 140, and 150 may be connected to the first node, and the other end thereof may be connected to the second node. The unit cells included in each of the capacitor units 110, 120, 130, 140, and 150 are connected in parallel as described above, and therefore, the unit cells C1, C2, C3, C4, and C5 included in the first embodiment 100 of the present invention are connected to each other in parallel through the first node and the second node.

The first embodiment 100 of the present invention may include a decoder (not shown) having a plurality of output terminals which are connected to each of the plurality of capacitor units 110, 120, 130, 140, and 150.

In the first embodiment 100 of the present invention, connection positions of the capacitors c11, c12, c21, c22, c31, c32, c41, c42, c51, and c52 included in the unit cells C1, C2, C3, C4, and C5 may be different for each capacitor unit.

For example, referring to FIG. 1, the capacitors c11 and c12 included in the unit cell C1 of the capacitor unit 110 are respectively located at a first end and a fourth end of the unit cell C1. Accordingly, two switch transistors are located between the capacitors c11 and c12, and five switch transistors are located at a rear end of the capacitor c12.

The capacitors c21 and c22 included in the unit cell C2 of the capacitor unit 120 are respectively located at a second end and a fifth end of the unit cell C1. Accordingly, a single switch transistor is located at a front end of the capacitor c11, two switch transistors are located between the capacitors c21 and c22, and four switch transistors are located at a rear end of the capacitor c22.

In this manner, a connection position of the capacitors c31 and c32 included in the unit cell C3 of the capacitor unit 130, a connection position of the capacitors c41 and c42 included in the unit cell C4 of the capacitor unit 140, and a connection position of the capacitors c51 and c52 included in the unit cell C5 of the capacitor unit 150 may be mutually different for each capacitor unit.

In this manner, in a case in which the connection position of the capacitors included in the unit cells C1, C2, C3, C4, and C5 of each of the capacitor units 110, 120, 130, 140, and 150 is different for each capacitor unit, the first embodiment 100 of the present invention may adjust a difference in quality in accordance with a signal direction.

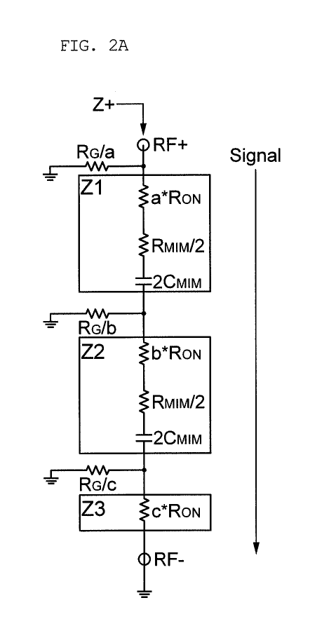

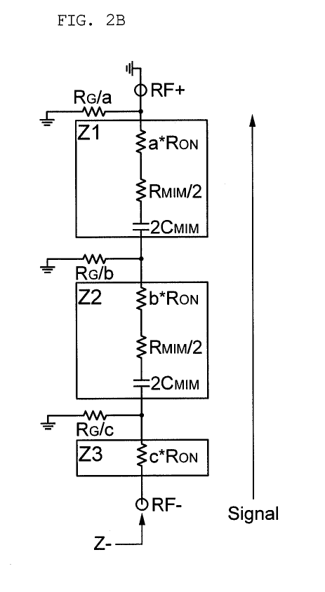

FIGS. 2A and 2B are equivalent circuit diagrams of a unit cell included in the present invention. Specifically, FIG. 2A is an equivalent circuit diagram when a signal is transmitted from the first node to the second node, and FIG. 2B is an equivalent circuit diagram when a signal is transmitted from the second node to the first node. Here, R_{G} denotes a resistance value of a gate resistor (not shown) connected to a gate terminal of each switch transistor, R_{ON} denotes a resistance value of a switch transistor in an ON state, and R_{MIM} denotes a resistance value of a capacitor having an MIM structure.

When it is assumed that a unit cell shown in FIG. 2 is the unit cell C2 of FIG. 1, a denotes the number of switch transistors located at a front end of the capacitor c21, b denotes the number of switch transistors located between the capacitors c21 and c22, and c denotes the number of switch transistors located at a rear end of the capacitor c22. Accordingly, referring to FIGS. 2A and 2B, an input impedance (Z+) when a signal is transmitted from the first node to the second node is represented as the following equation 1.

Z+=[[[[[Z3//(R_{G}/c)]+Z2]//(R_{G}/b)]+Z1]//(R_{G}/a)] [Equation 1]

An input impedance (Z−) when a signal is transmitted from the second node to the first node is represented as the following equation 2.

Z−=[[[[[(R_{G}/a)+Z1]+(R_{G}/b)]+Z2]//(R_{G}/c)]//Z3] [Equation 2]

In this manner, referring to Equations 1 and 2, it has been found that, when the switch transistor is in an ON state, the input impedance (Z+) when the signal is transmitted from the first node to the second node and the input impedance (Z−) when the signal is transmitted from the second node to the first node are different from each other. However, the impedances (Z+) and (Z−) are functions of a, b, and c, and therefore, when connection positions of the capacitors c11, c12, c21, c22, c31, c32, c41, c42, c51, and c52 included in the unit cells C1, C2, C3, C4, and C5 of each of the capacitor units 110, 120, 130, 140, and 150 are mutually different for each capacitor unit to thereby adjust values of a, b, and c, a difference in quality in accordance with a signal direction in the variable capacitor circuit may be adjusted.

Meanwhile, in the first embodiment 100 of the present invention, the number of capacitors and the number of switch transistors which are included in the unit cells C1, C2, C3, C4, and C5 may be mutually different for each unit cell. In this case, the impedances (Z+) and (Z−) may be adjusted by various parameters, and therefore, the difference in the quality in accordance with the signal direction may be more flexibly adjusted.

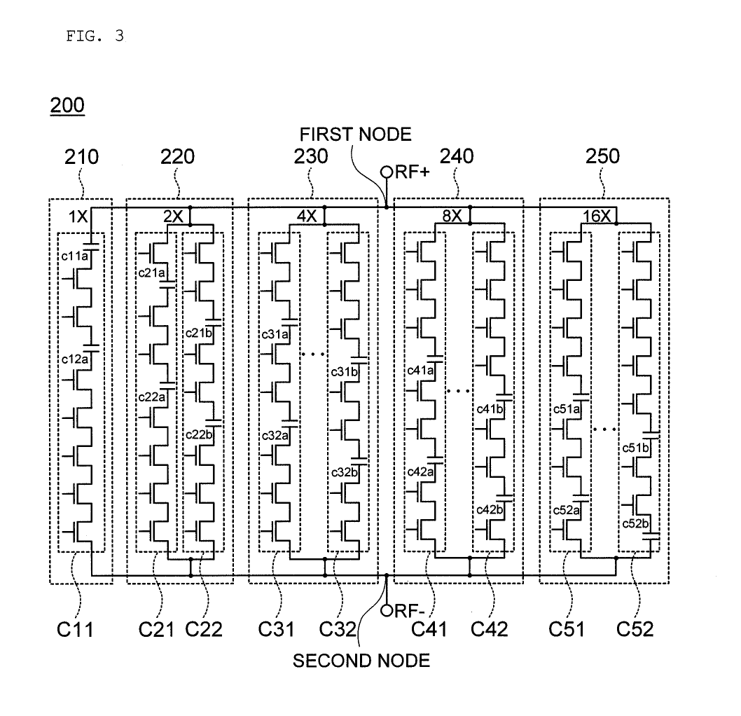

FIG. 3 is a detailed circuit diagram for explaining a second embodiment of the present invention.

Referring to FIG. 3, a second embodiment 200 of the present invention includes a plurality of capacitor units 210, 220, 230, 240, and 250, and each of the capacitor units 210, 220, 230, 240, and 250 includes at least one unit cell C11, C21, C22, C31, C32, C41, C42, C51, and C52. When each of the capacitor units 210, 220, 230, 240, and 250 includes at least two unit cells, the respective unit cells are connected to each other in parallel.

Each of the unit cells C11, C21, C22, C31, C32, C41, C42, C51, and C52 includes the unit cell C11, for example, capacitors c11a and c12a and a switch transistor which are connected in series to each other, and each of the number of capacitors and the number of switch transistors is configured as at least one. A gate resistor (R_{G}) is connected to a gate terminal of each switch transistor; however, is omitted for simplification of drawing.

In order that a capacitance value (C) of the variable capacitor circuit is varied in a binary scheme, the number of unit cells included in each of the capacitor units 210, 220, 230, 240, and 250 may be set to be different for each capacitor unit, and in this instance, a capacitance value (C) of each unit cell is preferably “1”.

An end of each of the plurality of capacitor units 210, 220, 230, 240, and 250 may be connected to the first node, and the other end thereof may be connected to the second node. The second embodiment 200 of the present invention may include a decoder (not shown) having a plurality of output terminals which are connected to each of the plurality of capacitor units 210, 220, 230, 240, and 250.

In the second embodiment 200 of the present invention, connection positions of the capacitors included in the unit cells C11, C21, C22, C31, C32, C41, C42, C51, and C52 may be mutually different for each unit cell.

For example, referring to FIG. 3, the capacitors c21a and c22a included in the unit cell C21 of the capacitor unit 220 are respectively located at a second end and a fifth end of the unit cell C21, and the capacitors c21b and c22b included in the unit cell C22 of the capacitor unit 220 are respectively located at a third end and a sixth end of the unit cell C22. That is, even in a case of the unit cells included in the same capacitor unit, the connection positions of the capacitors included in the unit cell are mutually different for each unit cell, and this is the same in the capacitor units 210, 230, 240, and 250.

Meanwhile, in the second embodiment 200 of the present invention, the number of capacitors included in the unit cells C11, C21, C22, C31, C32, C41, C42, C51, and C52 and the number of switch transistors may be mutually different for each unit cell.

As set forth above, according to the embodiments of the present invention, there is provided the variable capacitor circuit which may adjust a difference in quality factors in accordance with a signal direction.

The above detailed description exemplifies the present invention. Further, the above contents just illustrate and describe preferred embodiments of the present invention and the present invention can be used under various combinations, changes, and environments. That is, it will be appreciated by those skilled in the art that substitutions, modifications and changes may be made in these embodiments without departing from the principles and spirit of the general inventive concept, the scope of which is defined in the appended claims and their equivalents. Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Therefore, the detailed description of the present invention does not intend to limit the present invention to the disclosed embodiments. Further, it should be appreciated that the appended claims include even another embodiment.

What is claimed is:

1. A variable capacitor circuit, comprising:
a unit cell in which at least one switching unit and at least one capacitor are alternately connected in series to each other; and
a plurality of capacitor units to which at least one of the unit cells is connected in parallel,
wherein a capacitance value (C) is adjusted in accordance with ON/OFF of the switching unit in a manner such that an end of each of the plurality of capacitor units is connected to a first node, and the other end thereof is connected to a second node.

2. The variable capacitor circuit according to claim 1, wherein the number of unit cells included in each capacitor unit is mutually different for each capacitor unit.

3. The variable capacitor circuit according to claim 1, wherein the number of switching units and the capacitors included in each unit cell is mutually different for each unit cell.

4. The variable capacitor circuit according to claim 1, wherein the switching unit includes at least one switch transistor which is connected in series, and the number of switch transistors is mutually different for each switching unit.

5. The variable capacitor circuit according to claim 1, wherein the number of unit cells included in each capacitor unit is mutually different for each capacitor unit, the number of switching units and capacitors which are included in each unit cell is mutually different for each unit cell, the switching unit includes at least one switch transistor which is connected in series, and the number of switch transistors included in each switching unit is mutually different for each switching unit.

6. The variable capacitor circuit according to claim 1, wherein the capacitance value (C) of each unit cell is 1.

7. The variable capacitor circuit according to claim 1, wherein the capacitor has a Metal Insulator Metal (MIM) structure.

8. The variable capacitor circuit according to claim 1, further comprising:
a decoder having a plurality of output terminals which are connected to each of the plurality of capacitor units.

9. A variable capacitor circuit which is composed of a plurality of capacitor units,
wherein each capacitor unit includes at least one unit cell, the unit cell includes at least one switch transistor and at least one capacitor which are connected in series to each other, and a connection position of the capacitor is mutually different for each capacitor unit.

10. The variable capacitor circuit according to claim 9, wherein the number of capacitors and switch transistors included in the unit cell is mutually different for each unit cell.

11. The variable capacitor circuit according to claim 9, wherein the number of unit cells included in each capacitor unit is mutually different for each capacitor unit.

12. The variable capacitor circuit according to claim 9, wherein the number of capacitors and switch transistors included in the unit cell is mutually different for each capacitor unit, and the number of unit cells included in each capacitor unit is mutually different for each capacitor unit.

13. A variable capacitor circuit which is composed of a plurality of capacitor units,
wherein each capacitor unit includes at least one unit cell, the unit cell includes at least one switch transistor and at least one capacitor which are connected in series to each other, and a connection position of the capacitor is mutually different for each unit cell.
